(19) United States
(12) Patent Application Publication
(10) Pub. No.: US 2026/0150422 A1
(43) Pub. Date: May 28, 2026

(54) Image Sensors with Photodiodes and Isolation Structures

(71) Applicant: SEMICONDUCTOR COMPONENTS INDUSTRIES, LLC, Scottsdale, AZ (US)

(72) Inventors: Federico PACE, Antwerp (BE); Manuel H. INNOCENT, Wezemaal (BE); Konstantin G. KORABLEV, Penfield, NY (US)

(73) Assignee: SEMICONDUCTOR COMPONENTS INDUSTRIES, LLC, Scottsdale, AZ (US)

(21) Appl. No.: 18/958,337

(22) Filed: Nov. 25, 2024

(51) Int. Cl. H01L 27/146

(52) U.S. Cl. CPC H10F 39/807; H10F 39/80377; H10F 39/8053; H10F 39/8063

(57) ABSTRACT

An image sensor device may include a semiconductor substrate and photodiodes for imaging pixels in the semiconductor substrate. Deep trench isolation (DTI) structures may be used to isolate adjacent imaging pixels from one another. The photodiodes may include elongated n-type doped semiconductor portions that extend parallel to the deep trench isolation structures. A p-type doped semiconductor portion may be interposed between first and second elongated n-type doped semiconductor portions. The elongated n-type doped semiconductor portions may be formed by implanting dopants through side surfaces of trenches that define the DTI structures. Plasma assisted doping may be used to implant dopants through side surfaces of trenches that define the DTI structures.

### BACKGROUND

Image sensors are commonly used in electronic devices such as cellular telephones, cameras, computers, and automobiles to capture images. In a typical arrangement, an image sensor includes an array of image pixels arranged in pixel rows and pixel columns. Circuitry may be coupled to each pixel column for reading out image signals from the image pixels.

It is within this context that the embodiments described herein arise.

### BRIEF DESCRIPTION OF THE DRAWINGS

FIG. 1 is a diagram of an illustrative electronic device having an image sensor in accordance with some embodiments.

FIG. 2 is a diagram of an illustrative pixel array and associated row and column control circuitry for reading out image signals from an image sensor in accordance with some embodiments.

FIG. 3 is a circuit diagram of an illustrative image pixel in accordance with some embodiments.

FIG. 4 is a cross-sectional side view of an illustrative image sensor with an imaging pixel comprising a photodiode having elongated doped portions that extend parallel to isolation structures and a vertical transfer gate in accordance with some embodiments.

FIG. 5 is a cross-sectional side view of an illustrative image sensor with an imaging pixel comprising a photodiode having elongated doped portions that extend parallel to isolation structures and a horizontal transfer gate in accordance with some embodiments.

FIG. 6 is a flowchart of an illustrative method for forming an image sensor with an imaging pixel comprising a photodiode having elongated doped portions that extend parallel to isolation structures in accordance with some embodiments.

FIG. 7 is a side view of an illustrative method for implanting dopants through side surfaces of a semiconductor substrate in accordance with some embodiments.

FIG. 8 is a top view of an illustrative imaging pixel comprising a photodiode having elongated doped portions that extend parallel to isolation structures in accordance with some embodiments.

### DETAILED DESCRIPTION

Embodiments of the present technology relate to image sensors. It will be recognized by one skilled in the art that the present exemplary embodiments may be practiced without some or all of these specific details. In other instances, well-known operations have not been described in detail in order not to unnecessarily obscure the present embodiments.

Electronic devices such as digital cameras, computers, cellular telephones, and other electronic devices may include image sensors that gather incoming light to capture an image. The image sensors may include arrays of pixels. The pixels in the image sensors may include photosensitive elements such as photodiodes that convert the incoming light into image signals. Image sensors may have any number of pixels, such as hundreds or thousands or more. A typical image sensor may, for example, have hundreds or thousands or millions of pixels. One million pixels may be referred to as a megapixel. Image sensors may include control circuitry such as circuitry for operating the pixels and readout circuitry for reading out image signals corresponding to the electric charge generated by the photosensitive elements.

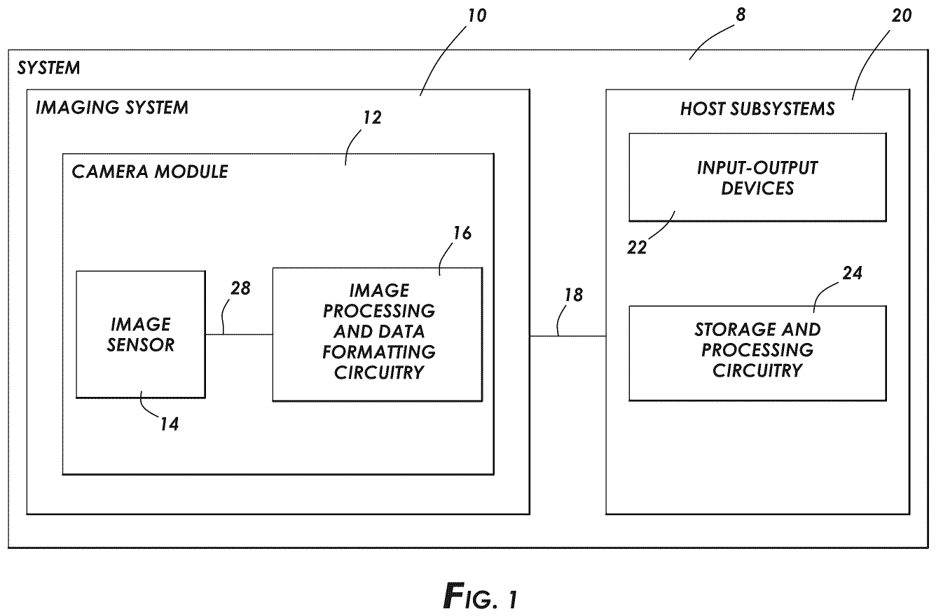

FIG. 1 is a diagram of an illustrative imaging and response system including an imaging system that uses an image sensor to capture images. System 8 of FIG. 1 may be an electronic device such as a camera, a cellular telephone, a video camera, or other electronic device that captures digital image data, may be a vehicle safety system (e.g., an active braking system or other vehicle safety system), or may be a surveillance system, as examples.

As shown in FIG. 1, system 8 may include an imaging system such as imaging system 10 and host subsystems such as host subsystem 20. Imaging system 10 may include camera module 12. Camera module 12 may include one or more image sensors 14, such as in an image sensor array integrated circuit, and one or more lenses. During image capture operations, each lens may focus light onto an associated image sensor 14. Image sensor 14 may include photosensitive elements (e.g., image sensor pixels) that convert the light into analog data. Image sensors may have any number of pixels, such as hundreds, thousands, millions, or more. A typical image sensor may, for example, have millions of pixels (e.g., megapixels).

Each image sensor in camera module 12 may be identical or there may be different types of image sensors in a given image sensor array integrated circuit. In some examples, image sensor 14 may further include bias circuitry (e.g., source follower load circuits), sample and hold circuitry, correlated double sampling (CDS) circuitry, amplifier circuitry, analog-to-digital converter circuitry, data output circuitry, memory (e.g., buffer circuitry), and/or address circuitry.

Still and video image data from image sensor 14 may be provided to image processing and data formatting circuitry 16 via path 28. Image processing and data formatting circuitry 16 may be used to perform image processing functions such as data formatting, adjusting white balance and exposure, implementing video image stabilization, or face detection. Image processing and data formatting circuitry 16 may additionally or alternatively be used to compress raw camera image files if desired, such as compressing the raw camera image files to Joint Photographic Experts Group (JPEG) format.

In one example arrangement, such as a system on chip (SoC) arrangement, image sensor 14 and image processing and data formatting circuitry 16 are implemented on a common semiconductor substrate, such as a common silicon image sensor integrated circuit die. If desired, image sensor 14 and image processing and data formatting circuitry 16 may be formed on separate semiconductor substrates. For example, image sensor 14 and image processing and data formatting circuitry 16 may be formed on separate substrates that have been stacked.

Imaging system 10 may convey acquired image data to host subsystem 20 over path 18. Host subsystem 20 may include input-output devices 22 and storage and processing circuitry 24. Host subsystem 20 may include processing software for detecting objects in images, detecting motion of objects between image frames, determining distances to objects in images, or filtering or otherwise processing images provided by imaging system 10. For example, image processing and data formatting circuitry 16 of imaging system 10 may communicate the acquired image data to storage and processing circuitry 24 of host subsystems 20.

If desired, system 8 may provide a user with numerous high-level functions. In a computer or cellular telephone, for example, a user may be provided with the ability to run user applications. For these functions, input-output devices 22 of host subsystem 20 may include keypads, input-output ports, buttons, and displays and storage and processing circuitry 24. Storage and processing circuitry 24 of host subsystem 20 may include volatile and/or nonvolatile memory (e.g., random-access memory, flash memory, hard drives, and/or solid-state drives). Storage and processing circuitry 24 may additionally or alternatively include microprocessors, microcontrollers, digital signal processors, and/or application specific integrated circuits.

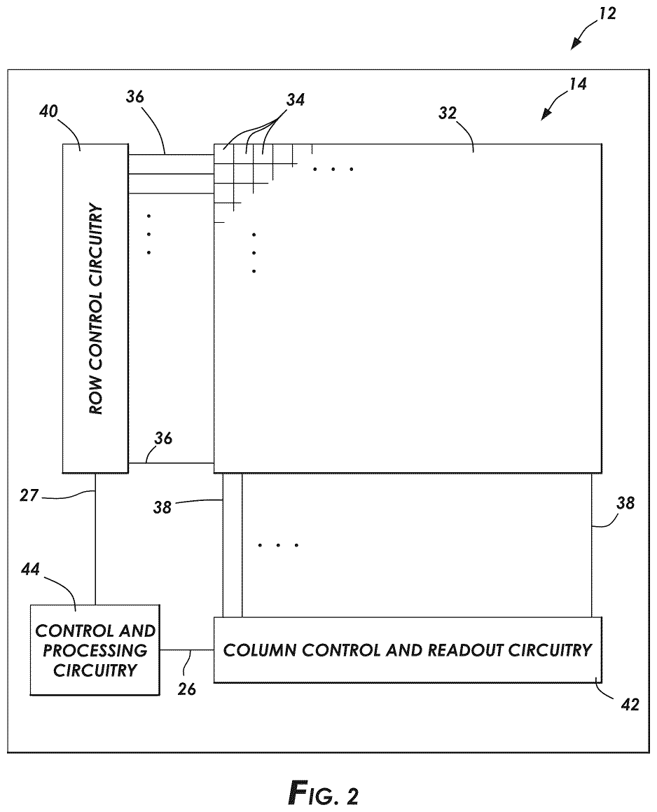

An example of an arrangement of image sensor 14 of FIG. 1 is shown in FIG. 2. As shown in FIG. 2, image sensor 14 may include control and processing circuitry 44. Control and processing circuitry 44 (sometimes referred to as control and processing logic herein) may be part of image processing and data formatting circuitry 16 in FIG. 1 or may be separate from image processing and data formatting circuitry 16. Image sensor 14 may include a pixel array such as array 32 of pixels 34 (sometimes referred to herein as image sensor pixels, imaging pixels, or image pixels). Control and processing circuitry 44 may be coupled to row control circuitry 40 via control path 27 and may be coupled to column control and readout circuitry 42 via data path 26.

Row control circuitry 40 may receive row addresses from control and processing circuitry 44 and may supply corresponding row control signals to image pixels 34 over one or more control paths 36. The row control signals may include pixel reset control signals, charge transfer control signals, blooming control signals, row select control signals, dual conversion gain control signals, and/or any other desired pixel control signals.

Column control and readout circuitry 42 may be coupled to one or more of the columns of pixel array 32 via one or more conductive lines such as column lines 38. A given column line 38 may be coupled to a column of image pixels 34 in image pixel array 32 and may be used for reading out image signals from image pixels 34 and for supplying bias signals (e.g., bias currents or bias voltages) to image pixels 34. In some examples, each column of pixels may be coupled to a corresponding column line 38. For image pixel readout operations, a pixel row in image pixel array 32 may be selected using row control circuitry 40, and image data associated with image pixels 34 of that pixel row may be read out by column control and readout circuitry 42 on column lines 38. Column control and readout circuitry 42 may include column circuitry such as column amplifiers for amplifying signals read out from array 32, sample and hold circuitry for sampling and storing signals read out from array 32, analog-to-digital converter circuits for converting read out analog signals to corresponding digital signals, and/or column memory for storing the readout signals and any other desired data. Column control and readout circuitry 42 may output digital pixel readout values to control and processing circuitry 44 over data path 26.

Array 32 may have any number of rows and columns. In general, the size of array 32 and the number of rows and columns in array 32 will depend on the particular implementation of image sensor 14. While rows and columns are generally described herein as being horizontal and vertical, respectively, rows and columns may refer to any grid-like structure. Features described herein as rows may be arranged vertically and features described herein as columns may be arranged horizontally.

Pixel array 32 may be provided with a color filter array having multiple color filter elements which allows a single image sensor to sample light of different colors. As an example, image sensor pixels such as the image pixels in array 32 may be provided with a color filter array which allows a single image sensor to sample red, green, and blue (RGB) light using corresponding red, green, and blue image sensor pixels. The red, green, and blue image sensor pixels may be arranged in a Bayer mosaic pattern. The Bayer mosaic pattern consists of a repeating unit cell of two-by-two image pixels, with two green image pixels diagonally opposite one another and adjacent to a red image pixel diagonally opposite to a blue image pixel. In another example, broadband image pixels having broadband color filter elements (e.g., clear color filter elements) may be used instead of green pixels in a Bayer pattern. These examples are merely illustrative and, in general, color filter elements of any desired color (e.g., cyan, yellow, red, green, or blue) and in any desired pattern may be formed over any desired number of image pixels 34.

Pixels 34 of array 32 may be separated by trench isolation structures such as deep trench isolation (DTI) structures. The DTI structures may be frontside DTI structures formed at the front surface of a pixel substrate or may be backside DTI structures formed at the back surface of the pixel substrate. The DTI structures may be formed from dielectric material, such as silicon dioxide or another suitable dielectric, and/or may include a light absorbing material, such as tungsten.

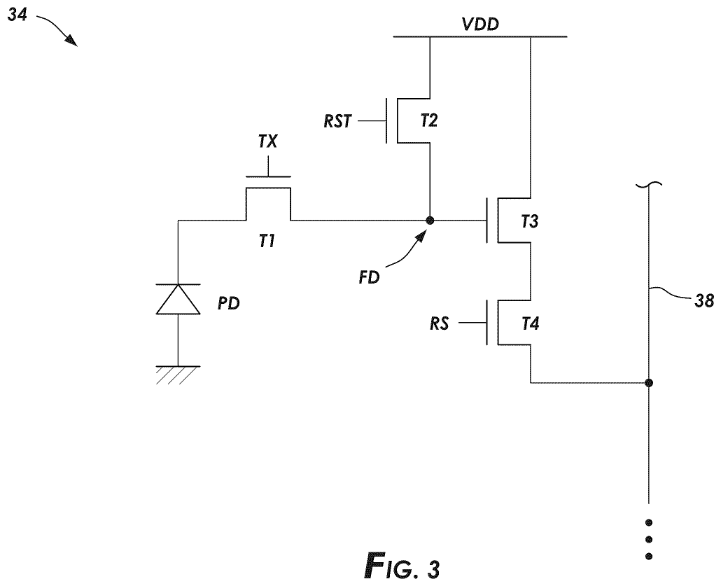

FIG. 3 is a circuit diagram of an illustrative image sensor pixel 34. As shown in FIG. 3, image sensor pixel 34 may include a photosensitive element such as a photodiode PD and a charge transfer transistor such as charge transfer transistor T1 having a first source-drain terminal coupled to photodiode PD, a second source-drain terminal coupled to floating diffusion node FD, and a gate terminal configured to receive charge transfer control signal TX. Photodiode PD has a p-type (anode) terminal coupled at a ground power supply line, sometimes referred to as a ground line or ground. Charge transfer transistor T1 is sometimes referred to as a charge transfer gate. Floating diffusion node FD is sometimes referred to as a floating diffusion region.

Pixel 34 may further include a reset transistor T2 having a drain terminal coupled to the positive power supply line on which positive power supply voltage VDD is provided, a source terminal coupled to floating diffusion node FD, and a gate terminal configured to receive a reset control signal RST. The terms “source” terminal and “drain” terminal when referring to current-conducting terminals of a metal-oxide-semiconducting (MOS) transistor can be used interchangeably and are sometimes referred to as “source-drain” terminals. For example, the drain terminal of reset transistor T2 can be referred to as its first source-drain terminal, and the source terminal of reset transistor T2 can be referred to as its second source-drain terminal, or vice versa.

Image pixel 34 may also include a source follower transistor T3 having a drain terminal coupled to the positive power supply line, a gate terminal coupled to floating diffusion node FD, and a source terminal. Source follower transistor T3 is sometimes simply referred to as a “source follower.” Pixel 34 may further include a row select transistor T4 having a drain terminal coupled to the source terminal of source follower T3, a gate terminal configured to receive a row select control signal RS, and a source terminal coupled to a corresponding column line 38. Column line 38 may be coupled to more than 10 pixels in a column of pixels, 10-100 pixels in the column, hundreds of pixels in the column, or thousands of pixels in the column. Column line 38 is sometimes referred to as a pixel output line or a pixel output column line.

In the example of FIG. 3, transistors T1-T4 may all be n-type metal-oxide-semiconductor (NMOS) transistors. In other embodiments, at least some transistors T1-T4 can alternatively be implemented as p-type metal-oxide-semiconductor (PMOS) transistors. In yet other embodiments, imaging pixel 34 can optionally include four or more n-channel and/or p-channel transistors. The example of FIG. 3 in which pixel 34 includes four transistor T1-T4 is also merely illustrative. In other embodiments, imaging pixel 34 can include multiple photodiodes coupled to a shared floating diffusion node, fewer than four transistors, more than four transistors, five or more transistors, six or more transistors, one or more storage capacitors, one or more storage nodes, one or more mode switching transistors, multi-conversion gain components, bloom control components, and/or other pixel structures. The imaging pixel 34 can be rolling shutter type pixels or global shutter type pixels such as pixels that include additional storage nodes coupled between the photodiode and the floating diffusion region.

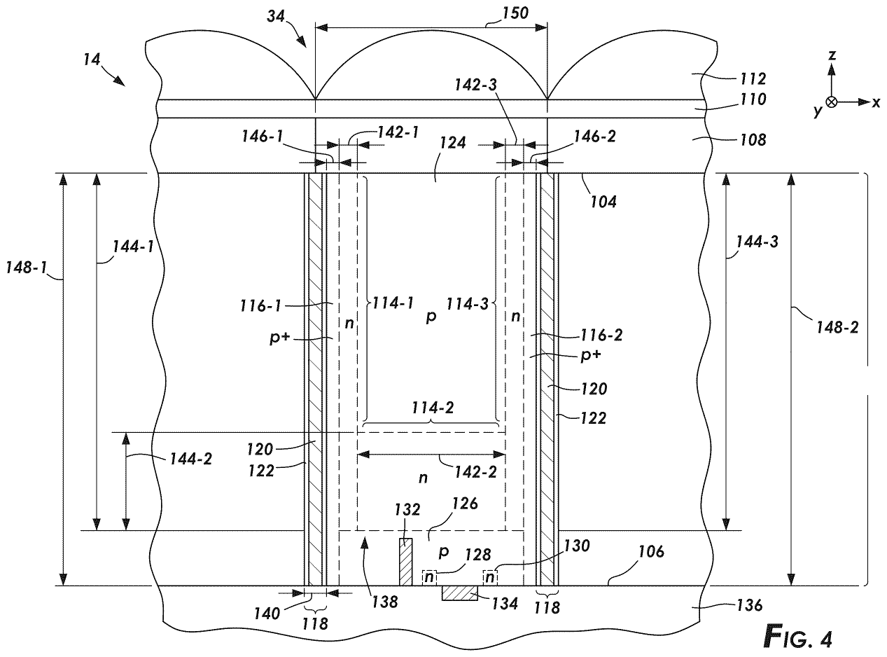

FIG. 4 is a cross-sectional side view of an illustrative image sensor 14 with an imaging pixel 34. As shown in FIG. 4, image sensor 14 may include a substrate such as a p-type semiconductor substrate 102 (sometimes referred to as p-type doped semiconductor substrate 102, p-doped semiconductor substrate 102, etc.). Substrate 102 has first and second opposing surfaces 104 and 106. Surface 104 may sometimes be referred to as a back surface whereas surface 106 may sometimes be referred to as a front surface. Front surface 106 may be adjacent to one or more interlayer dielectric layers 136, which may include an interconnect stack.

The interconnect stack formed by interlayer dielectric layers 136 may include alternating routing layers and via layers formed within a dielectric material, such as silicon dioxide, that forms interlayer dielectric 136. The interconnect stack may include at least two metal routing layers, at least three metal routing layers, four or more metal routing layers, five to ten metal routing layers, more than ten metal routing layers, or other number of conductive routing layers. The interconnect stack may be formed from copper, indium tin oxide (ITO), aluminum, tungsten, titanium, gold, silver, nickel, a metal alloy, a combination of metals, and/or other types of conductive material. The metal routing structures and the metal via structures can form an electrical network for interconnecting together various components within pixels 34 and for coupling image signals obtained from pixels 34 to corresponding image signal processing circuitry or other off-chip components.

Application-specific integrated circuitry and/or other circuitry may be coupled to interlayer dielectric 136. Application-specific integrated circuitry and/or other circuitry may receive signals generated by pixels 34, process the signals, and/or transmit the signals to other circuitry in an image sensing system.

An array of color filter structures may be formed over substrate 102. In the example of FIG. 4, each imaging pixel includes a corresponding color filter element 108. The color filter elements may be part of a color filter array (CFA) having red color filter elements, green color filter elements, blue color filter elements, cyan color filter elements, magenta color filter elements, yellow color filter elements, black color filter elements, clear (broadband) color filter elements, some combination of these color filter elements, and/or other color filter elements. The use of a CFA is optional and can be omitted for monochrome image sensors. A monochrome image sensor 14 can have clear (broadband) filter elements 108. A planarization layer such as planarization layer 110 may be formed on the color filter array.

An array of microlens structures 112 may be formed over the color filter array. Each microlens 112 may be configured to direct incoming light towards a corresponding photodiode within a respective imaging pixel. In the arrangement of FIG. 4, incident light enters semiconductor substrate 102 through back surface 104 and the image sensor of FIG. 4 may therefore be referred to as a backside illuminated (BSI) image sensing device.

The image sensor of FIG. 4 may include one or more pixel isolation structures. The pixel isolation structures may include deep trench isolation (DTI) structures such as DTI structures 118. The DTI structures may be formed at the front side of substrate 102 (e.g., through front surface 106), at the back side of substrate 102 (e.g., through back surface 104), and/or entirely through the thickness of substrate 102 (as shown in the example of FIG. 4). DTI structures 118 help provide enhanced electrical isolation between adjacent photodiodes/pixels. The DTI structures may optionally be formed only partially through the thickness of substrate 102.

DTI structures 118 include filler material 120 and a liner 122. Filler material 120 may comprise dielectric material such as silicon dioxide or another suitable dielectric. The dielectric filler material may have a lower refractive index than silicon substrate 102 (e.g., by more than 0.1, more than 0.2, more than 0.3, more than 0.5, more than 1.0, more than 1.5, more than 2.0, etc.) and may sometimes be referred to as a low-index dielectric filler. Instead or in addition to a dielectric material, filler material 120 may include a conductive material such as polysilicon or a light absorbing material such as tungsten.

Optional liner 122 may be formed at the interface between semiconductor substrate 102 and filler material 120. Liner 122 may be formed from an oxide such as silicon dioxide or from a high-k dielectric material such as aluminum oxide (Al₂O₃), hafnium oxide (HfO₂), tantalum oxide (Ta₂O₅), and/or other dielectric materials to help prevent the generation of dark current. Liner 122 is therefore sometimes referred to as a high-k dielectric layer or high-k dielectric liner.

FIG. 4 shows an illustrative photodiode arrangement for imaging pixel 34. In particular, photodiode 138 comprises a first n-type doped semiconductor region 114-1, a second n-type doped semiconductor region 114-2, a third n-type doped semiconductor region 114-3, a first p+ doped semiconductor region 116-1, a second p+ doped semiconductor region 116-2, p-type doped semiconductor region 124, and p-type doped semiconductor region 126.

P-type doped semiconductor refers to a semiconductor with a majority of charge carriers being holes. Illustrative p-type dopants may have three valence electrons and include boron, aluminum, and gallium. N-type doped semiconductor refers to a semiconductor with a majority of charge carriers being electrons. Illustrative n-type dopants may have five valence electrons and include phosphorous, arsenic, and antimony.

During manufacturing, substrate 102 may have an initial bulk p-type doping concentration. P-type doped semiconductor region 124 may receive no additional doping during the manufacturing process. P-type doped semiconductor region 124 therefore may have a p-type doping concentration that is equal to the initial bulk p-type doping concentration of substrate 102. P-type doped semiconductor region 124 and/or p-type doped semiconductor region 126 may optionally receive additional doping during the manufacturing process. This additional doping may be a masked or a blanket implant. P-type doped semiconductor region 126 may sometimes be referred to as a p-well.

Additional dopants may be added to substrate 102 during the manufacturing process. For example, additional p-type dopants may be added to regions 116-1 and 116-2 to cause regions 116-1 and 116-2 to have a higher p-type doping concentration than p-type doped semiconductor region 124 and p-type doped semiconductor region 126. Regions 116-1 and 116-2 are therefore referred to as p+ doped semiconductor regions. N-type dopants may be added to regions 114-1, 114-2, and 114-3 to cause regions 114-1, 114-2, and 114-3 to be n-type doped semiconductor regions.

The total thickness of substrate 102 may be greater than 2 microns, greater than 4 microns, greater than 5 microns, greater than 6 microns, greater than 8 microns, greater than 10 microns, between 4 microns and 10 microns, less than 15 microns, less than 10 microns, etc. The total width 150 of imaging pixel 34 may be greater than 0.5 microns, greater than 1 micron, greater than 2 microns, greater than 3 microns, less than 5 microns, less than 3 microns, less than 2 microns, between 1 micron and 3 microns, between 0.5 microns and 5 microns, etc.

DTI structure 118 may have a width 140 and a length that is equal to the thickness of substrate 102. The length of DTI structure 118 is greater than width 140. The length of DTI structure 118 may extend orthogonal to back surface 104 and/or front surface 106 of substrate 102. The magnitude of width 140 may be less than 1 micron, less than 0.5 microns, less than 0.3 microns, less than 0.2 microns, less than 0.1 micron, greater than 0.1 micron, between 0.1 micron and 0.2 microns, between 0.05 microns and 0.5 microns, etc.

N-type doped semiconductor region 114-1 may have a width 142-1 and a length 144-1. Length 144-1 is greater than width 142-1. N-type doped semiconductor region 114-1 may sometimes be referred to as an elongated n-type doped semiconductor region. The length of n-type doped semiconductor region 114-1 extends orthogonal to back surface 104 and/or front surface 106 of substrate 102. The length of n-type doped semiconductor region 114-1 also extends parallel to the length of DTI structure 118.

N-type doped semiconductor region 114-2 may have a width 144-2 and a length 142-2. Length 142-2 may be greater than width 144-2. The length of n-type doped semiconductor region 114-2 extends parallel to back surface 104 and/or front surface 106 of substrate 102. The length of n-type doped semiconductor region 114-2 also extends orthogonal to the length of DTI structure 118.

N-type doped semiconductor region 114-3 may have a width 142-3 and a length 144-3. Length 144-3 is greater than width 142-3. N-type doped semiconductor region 114-3 may sometimes be referred to as an elongated n-type doped semiconductor region. The length of n-type doped semiconductor region 114-3 extends orthogonal to back surface 104 and/or front surface 106 of substrate 102. The length of n-type doped semiconductor region 114-3 also extends parallel to the length of DTI structure 118.

P+ doped semiconductor region 116-1 has a first portion that is interposed between n-type doped semiconductor region 114-1 and DTI structure 118 and a second portion that is interposed between n-type doped semiconductor region 114-2 and DTI structure 118. P+doped semiconductor region 116-1 may have a width 146-1 and a length 148-1. Length 148-1 is greater than width 146-1. Length 148-1 may be equal to the thickness of substrate 102. P+ doped semiconductor region 116-1 may sometimes be referred to as an elongated p+ doped semiconductor region. The length of p+ doped semiconductor region 116-1 extends orthogonal to back surface 104 and/or front surface 106 of substrate 102. The length of p+ doped semiconductor region 116-1 also extends parallel to the length of DTI structure 118.

P+ doped semiconductor region 116-2 has a first portion that is interposed between n-type doped semiconductor region 114-3 and DTI structure 118 and a second portion that is interposed between n-type doped semiconductor region 114-2 and DTI structure 118. P+ doped semiconductor region 116-2 may have a width 146-2 and a length 148-2. Length 148-2 is greater than width 146-2. Length 148-2 may be equal to the thickness of substrate 102. P+ doped semiconductor region 116-1 may sometimes be referred to as an elongated p+ doped semiconductor region. The length of p+ doped semiconductor region 116-2 extends orthogonal to back surface 104 and/or front surface 106 of substrate 102. The length of p+ doped semiconductor region 116-2 also extends parallel to the length of DTI structure 118.

Widths 142-1 and 142-3 may each have a magnitude that is less than 1 micron, less than 0.5 microns, less than 0.3 microns, less than 0.2 microns, less than 0.1 micron, greater than 0.1 micron, between 0.1 micron and 0.2 microns, between 0.05 microns and 0.5 microns, etc. Each one of widths 142-1 and 142-3 may be less than 30% the total width 150 of imaging pixel 34, less than 20% the total width 150 of imaging pixel 34, less than 15% the total width 150 of imaging pixel 34, less than 10% the total width 150 of imaging pixel 34, less than 5% the total width 150 of imaging pixel 34, greater than 5% the total width 150 of imaging pixel 34, etc.

Lengths 144-1 and 144-3 may each have a magnitude that is greater than 2 microns, greater than 4 microns, greater than 6 microns, greater than 8 microns, greater than 10 microns, between 4 microns and 10 microns, less than 15 microns, less than 10 microns, etc. Each one of lengths 144-1 and 144-3 may be greater than 50% the total thickness of substrate 102, greater than 60% the total thickness of substrate 102, greater than 70% the total thickness of substrate 102, greater than 80% the total thickness of substrate 102, greater than 90% the total thickness of substrate 102, etc.

Length 144-1 may be greater than width 142-1 by a factor of 3 or more, by a factor of 5 or more, by a factor of 10 or more, by a factor of 20 or more, by a factor of 50 or more, etc. Length 144-3 may be greater than width 142-3 by a factor of 3 or more, by a factor of 5 or more, by a factor of 10 or more, by a factor of 20 or more, by a factor of 50 or more, etc.

Widths 146-1 and 146-2 may each have a magnitude that is less than 1 micron, less than 0.5 microns, less than 0.3 microns, less than 0.2 microns, less than 0.1 micron, greater than 0.1 micron, between 0.1 micron and 0.2 microns, between 0.05 microns and 0.5 microns, etc. Each one of widths 146-1 and 146-2 may be less than 30% the total width 150 of imaging pixel 34, less than 20% the total width 150 of imaging pixel 34, less than 15% the total width 150 of imaging pixel 34, less than 10% the total width 150 of imaging pixel 34, less than 5% the total width 150 of imaging pixel 34, greater than 5% the total width 150 of imaging pixel 34, etc.

Lengths 148-1 and 148-2 may each have a magnitude that is greater than 2 microns, greater than 4 microns, greater than 6 microns, greater than 8 microns, greater than 10 microns, between 4 microns and 10 microns, less than 15 microns, less than 10 microns, etc. Each one of lengths 148-1 and 148-2 may be greater than 50% the total thickness of substrate 102, greater than 60% the total thickness of substrate 102, greater than 70% the total thickness of substrate 102, greater than 80% the total thickness of substrate 102, greater than 90% the total thickness of substrate 102, etc.

Length 148-1 may be greater than width 146-1 by a factor of 3 or more, by a factor of 5 or more, by a factor of 10 or more, by a factor of 20 or more, by a factor of 50 or more, etc. Length 148-2 may be greater than width 146-2 by a factor of 3 or more, by a factor of 5 or more, by a factor of 10 or more, by a factor of 20 or more, by a factor of 50 or more, etc.

Length 142-2 may be greater than 50% the total width 150 of imaging pixel 34, greater than 60% the total width 150 of imaging pixel 34, greater than 70% the total width 150 of imaging pixel 34, greater than 80% the total width 150 of imaging pixel 34, greater than 90% the total width 150 of imaging pixel 34, etc. Width 144-2 may be less than 40% the total thickness of substrate 102, less than 30% the total thickness of substrate 102, less than 20% the total thickness of substrate 102, less than 10% the total thickness of substrate 102, etc.

N-type doped regions 114-1 and 114-3 may abut back surface 104 or may terminate within a threshold distance of back surface 104. The threshold distance may be 0.1 micron, 0.2 microns, 0.5 microns, 0.8 microns, 1 micron, etc.

The collective n-type region defined by regions 114-1, 114-2, and 114-3 may sometimes be referred to as U-shaped. P-type doped semiconductor region 124 is interposed between n-type doped semiconductor regions 114-1 and 114-3 (e.g., in a central portion of the U-shape).

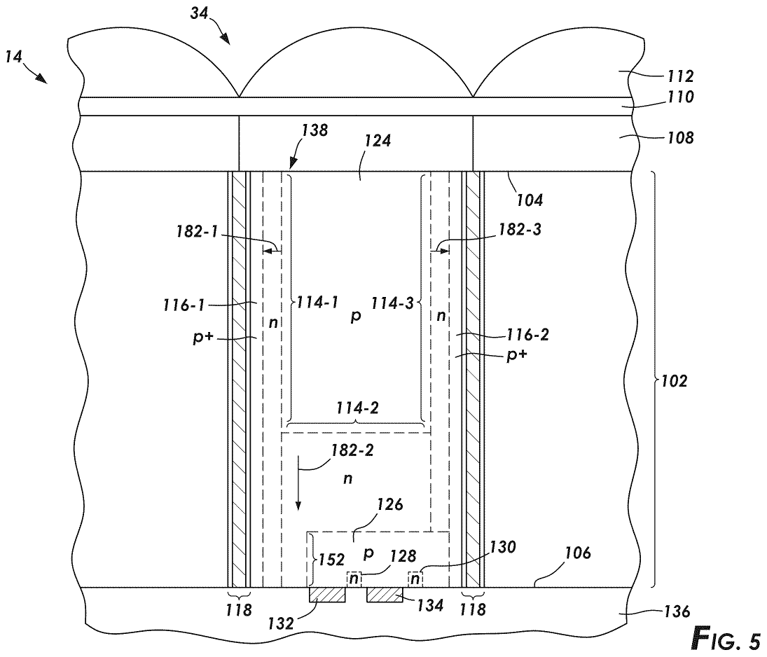

An imaging pixel with the photodiode arrangement shown in FIG. 4 may have any desired arrangement for additional pixel components such as a transfer gate, floating diffusion region, etc. FIGS. 4 and 5 show two different illustrative arrangements for pixel circuitry on the front side of substrate 102.

In the example of FIG. 4, the imaging pixel includes a vertical transfer gate 132. Gate 132 may be the gate for transfer transistor T1 in FIG. 3. The vertical transfer gate may have a width and a length that is greater than the width. The length extends orthogonal to front surface 106 and parallel to the Z-axis in FIG. 4. Floating diffusion region 128 (which may include an n-type doped semiconductor region) is adjacent to the vertical transfer gate. Vertical transfer gate 132 may transfer charge to floating diffusion region 128 when transfer transistor T1 is asserted. Reset transistor T2 from FIG. 3 may have a horizontal gate 134 that rests on front surface 106. Gate 134 may be interposed between floating diffusion region 128 and an additional n-type doped semiconductor region 130 that is connected to the power supply voltage VDD.

The vertical transfer gate in FIG. 4 may allow for a shallow photodiode implant to be omitted. The vertical transfer gate may have a width (parallel to the X-axis) that is greater than less than 1 micron, less than 0.5 microns, less than 0.3 microns, less than 0.2 microns, less than 0.1 micron, greater than 0.1 micron, between 0.1 micron and 0.3 microns, between 0.05 microns and 0.5 microns, etc. The vertical transfer gate may have a length (parallel to the Z-axis) that is greater than 0.2 microns, greater than 0.3 microns, greater than 0.4 microns, between 0.2 microns and 0.6 microns, less than 1 micron, less than 0.5 microns, etc. The vertical transfer gate is interposed between surfaces 104 and 106 and extends from surface 106 towards surface 104.

In an alternate example shown in FIG. 5, the imaging pixel again includes horizontal gate 134 (for reset transistor T2) between floating diffusion region 128 and n-type doped semiconductor region 130. However, in the example of FIG. 5 the transfer transistor gate 132 is a horizontal transfer gate that rests on front surface 106. Because a horizontal transfer gate is used in the arrangement of FIG. 5, photodiode 138 of FIG. 5 includes a shallow photodiode implant 152. The shallow photodiode implant may comprise an n-type doped semiconductor region. The shallow photodiode implant 152 may be considered part of n-type doped semiconductor region 114-2.

The pixel circuitry at front surface 106 may additionally include a source follower transistor, row select transistor, and/or any other desired pixel components.

Imaging pixels with the photodiode arrangement of FIGS. 4 and 5 may leverage the majority of the thickness of the semiconductor substrate for charge storage, thus improving full-well capacity (FWC) for the imaging pixels. Additionally, p+ doped semiconductor regions 116-1 and 116-2 may mitigate dark current associated with DTI 118.

One technique of doping a semiconductor substrate is to implant the dopants through the front surface or back surface of the substrate using a linear ion beam. However, the dopant depth may be limited (e.g., to 3 microns or less) with this type of implanting process. To increase the depth of the photodiode as in the arrangement of FIGS. 4 and 5, the n-type regions 114-1 and 114-3 in FIGS. 4 and 5 may formed by implanting dopants through a side surface of substrate 102 that defines a trench for DTI structures 118. In this way, the n-type doped regions 114-1 and 114-3 conform to the sides of the pixels defined by DTI structures 118 and abut back surface 104.

FIG. 5 shows how, as a result of being formed by implants through side surfaces of semiconductor substrate, n-type doped semiconductor regions 114-1 and 114-3 may have dopant concentration gradients that are parallel to front surface 106 and back surface 104. As shown in FIG. 5, n-type doped semiconductor region 114-1 may have a doping concentration gradient 182-1 where the doping concentration increases with decreasing separation from DTI structure 118. Similarly, n-type doped semiconductor region 114-3 may have a doping concentration gradient 182-3 where the doping concentration increases with decreasing separation from DTI structure 118.

In contrast with n-type doped semiconductor regions 114-1 and 114-3, n-type doped semiconductor region 114-2 may have a doping concentration gradient that is orthogonal to front surface 106 and back surface 104 (e.g., as a result of being formed by implants through front surface 106). As shown in FIG. 5, n-type doped semiconductor region 114-2 may have a doping concentration gradient 182-2 where the doping concentration increases with decreasing separation from front surface 106.

The doping concentration in n-type doped semiconductor region 114-2 may be different than the doping concentration in n-type doped semiconductor regions 114-1 and 114-3. The doping concentration gradients shown in FIG. 5 are merely illustrative. In general, each doped semiconductor region may have any desired doping concentration gradient.

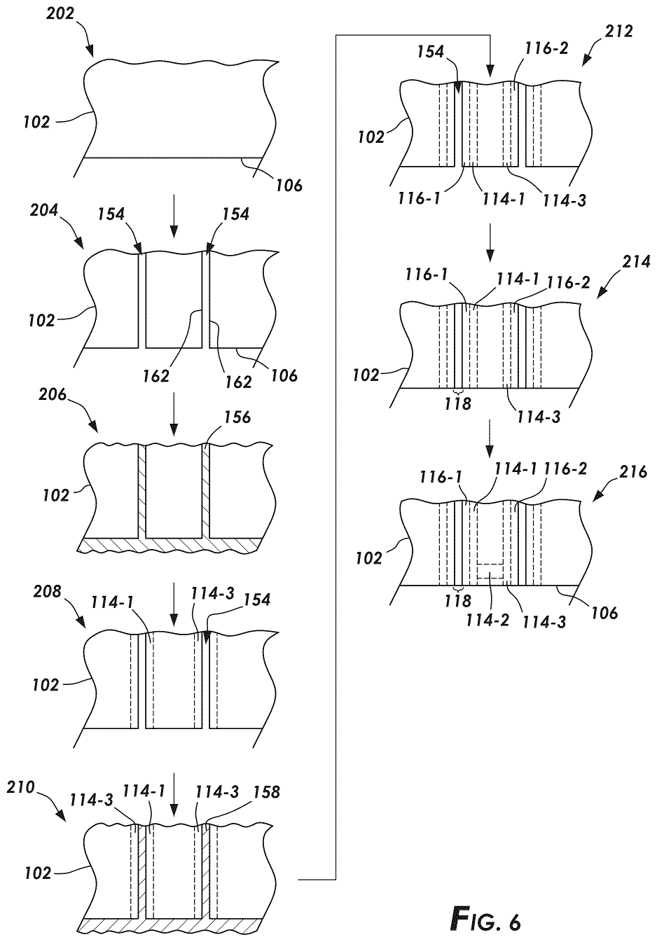

FIG. 6 is a flowchart showing an illustrative method for forming an imaging pixel with a U-shaped n-type doped region of the type shown in FIGS. 4 and 5. At step 202, semiconductor substrate 102 may have an initial p-type dopant concentration. At step 202, semiconductor substrate may have a thickness that is greater than the final thickness of the semiconductor substrate in the image sensor (e.g., as in FIGS. 4 and 5). At step 204, trenches 154 may be formed in the substrate. In the example of FIG. 6, trenches 154 are etched from the front surface 106 towards the back surface of the substrate. Trenches 154 may not extend completely through substrate 102. However, the trenches may extend to a depth that is greater than or equal to the final thickness of the semiconductor substrate in the image sensor. This example is merely illustrative and the trenches may extend from the backside of the substrate if desired.

After forming the trenches, n-type dopants may be implanted through side surfaces 162 of substrate 102 that are exposed by trenches 154 at step 206. To implant the n-type dopants through the side surfaces, a plasma assisted doping (PLAD) process may be used. The PLAD process may include filling trenches 154 with gas 156 at step 206. Gas 156 may comprise an n-type dopant. A high frequency voltage may then be applied to substrate 102 causing ions from gas 156 to enter substrate 102 through side surfaces 162. As shown at step 208, the resulting n-type doped regions 114-1 and 114-3 may extend parallel to side surfaces 162 and trenches 154.

After implanting the n-type dopants through the side surfaces, p-type dopants may be implanted through side surfaces 162 of substrate 102 that are exposed by trenches 154 at step 210. To implant the p-type dopants through the side surfaces, a plasma assisted doping (PLAD) process may be used. The PLAD process may include filling trenches 154 with gas 158 at step 210. Gas 158 may comprise a p-type dopant. A high frequency voltage may then be applied to substrate 102 causing ions from gas 158 to enter substrate 102 through side surfaces 162. As shown at step 212, the resulting p+ doped regions 116-1 and 116-3 may extend parallel to side surfaces 162 and trenches 154.

After doped regions 114-1, 114-3, 116-1, and 116-2 are formed, the trenches may be filled (e.g., with filler material 120 and liner 122 as shown in FIG. 4) to form DTI structures 118 in the trenches at step 214. Finally, an additional n-type region 114-2 may be formed in substrate 102 by implanting n-type dopants through front surface 106 of substrate 102 at step 216.

Subsequent processing may be performed after step 216 to form color filters 108 and microlenses 112 on the back side of substrate 102 as well as pixel circuitry on the front side of substrate 102 (e.g., transfer transistor gate 132, reset transistor gate 134, floating diffusion region 128, n-type doped region 130, etc.). The subsequent processing may include attaching the semiconductor substrate to a handling wafer and thinning the semiconductor substrate from the backside of the semiconductor substrate to define the back surface and final thickness of the semiconductor substrate shown in FIGS. 4 and 5.

It is noted that one or more anneal processes may be performed during the method shown in FIG. 6. During an anneal step, the semiconductor substrate may be heated (e.g., by placing the semiconductor substrate in an oven or by targeting the semiconductor substrate using a laser). An anneal step may cause diffusion of the n-type and/or p-type dopants to increase the depth of the dopants.

As one example, a first anneal step may be performed after step 208 to cause the n-type dopants for regions 114-1 and 114-3 to diffuse further from side surfaces 162. A second anneal step may be performed after step 212 to cause the p-type dopants for regions 116-1 and 116-2 to diffuse further from side surfaces 162.

As another example, a shared anneal step may be performed after step 212 to cause both the p-type dopants for regions 116-1 and 116-2 and the n-type dopants for regions 114-1 and 114-3 to diffuse further from side surfaces 162.

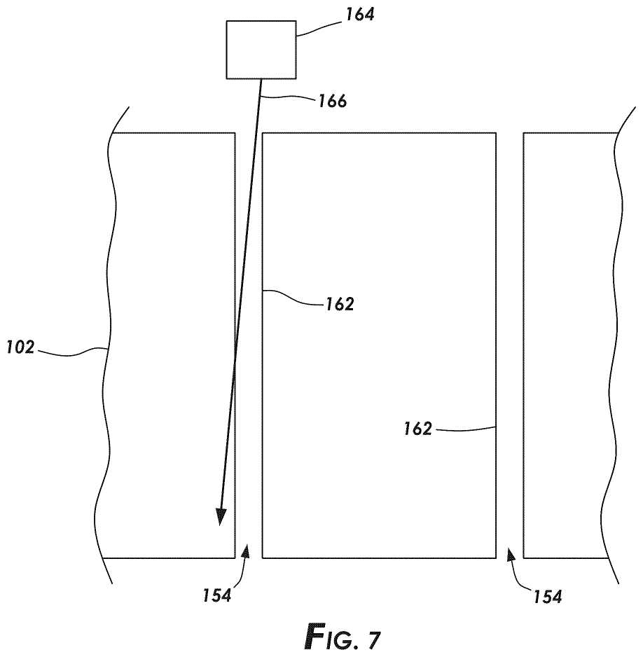

The example in FIG. 6 of implanting dopants through side surfaces 162 of substrate 102 using PLAD is merely illustrative. In another possible arrangement, shown in FIG. 7, dopants may be implanted using ion implantation equipment 164 that emits a linear ion beam 166 through trench 154. The ion implantation process may comprise a quad implant where the implantation is performed at 0 degrees, 90 degrees, 180 degrees, and 270 degrees. Although ion beam 166 is linear, the geometry of trench 154 may allow for the linear ion beam to implant ions through side surfaces 162 up to a depth determined by the width of trench 154. A wide trench may allow for implantation to a greater depth than a narrow trench. Alternatively, a greater implantation depth may be reached by increasing the angle of the ion beam slightly and having the ions bounce between the sides of the trenches.

Ion implantation through side surfaces 162 using a linear ion beam may optionally be used to implant n-type dopants for n-type doped semiconductor regions 114-1 and 144-3 and/or p-type dopants for p+ doped semiconductor regions 116-1 and 116-2.

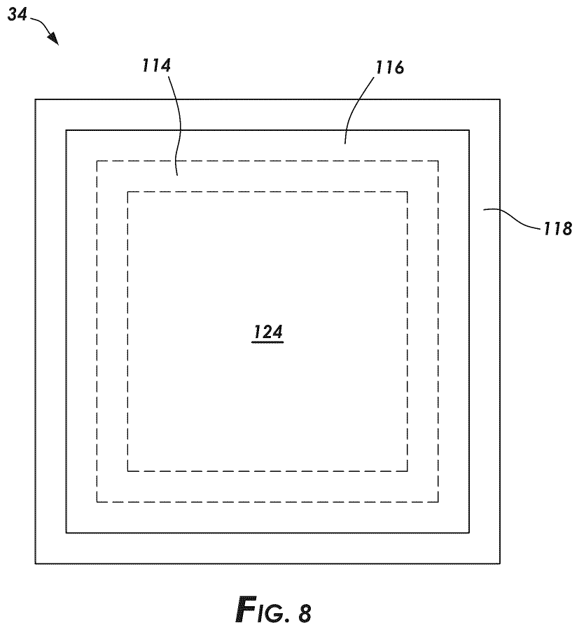

The depictions in FIGS. 4 and 5 of n-type doped semiconductor regions 114-1 and 114-3 being discrete regions are merely illustrative. The n-type doped semiconductor regions 114-1 and 114-3 may be part of a continuous n-type doped semiconductor region that extends in a ring around a periphery of imaging pixel 34. Similarly, the depictions in FIGS. 4 and 5 of p+ doped semiconductor regions 116-1 and 116-2 being discrete regions are merely illustrative. The p+ doped semiconductor regions 116-1 and 116-2 may be part of a continuous p+ doped semiconductor region that extends in a ring around a periphery of imaging pixel 34. FIG. 8 is a top view of an illustrative imaging pixel showing ring-shaped doped semiconductor regions.

As shown in FIG. 8, DTI structure 118 may extend in a ring around the periphery of imaging pixel 34. P+ doped semiconductor region 116 may conform to DTI structure 118 and extends in a ring around the periphery of imaging pixel 34. N-type doped semiconductor region 114 may conform to DTI structure 118 and p+ doped semiconductor region 116 and extends in a ring around the periphery of imaging pixel 34. DTI structure 118, p+ doped semiconductor region 116, and n-type doped semiconductor region 114 may be concentric. DTI structure 118, p+ doped semiconductor region 116, and n-type doped semiconductor region 114 may each have central openings that include p-type doped semiconductor region 124.

The foregoing is merely illustrative and various modifications can be made to the described embodiments. The foregoing embodiments may be implemented individually or in any combination.

What is claimed is:

1. An image sensor having an imaging pixel, the image sensor comprising:
a semiconductor substrate having first and second opposing surfaces and a thickness between the first and second surfaces that is greater than 4 microns;
one or more isolation structures that extend around a periphery of the imaging pixel; and
a photodiode for the imaging pixel, wherein the photodiode comprises:
a first n-type doped region in the semiconductor substrate, wherein the first n-type doped region has a first length that extends parallel to the one or more isolation structures and wherein the first length is greater than 60% the thickness;
a second n-type doped region in the semiconductor substrate, wherein the second n-type doped region has a second length that extends parallel to the one or more isolation structures and wherein the second length is greater than 60% the thickness; and
a p-type doped region in the semiconductor substrate that is interposed between the first and second n-type doped regions.

2. The image sensor defined in claim 1, further comprising:
a first p+ doped region in the semiconductor substrate that is interposed between the first n-type doped region and the one or more isolation structures; and
a second p+ doped region in the semiconductor substrate that is interposed between the second n-type doped region and the one or more isolation structures.

3. The image sensor defined in claim 2, wherein the first p+ doped region has a third length that extends parallel to the one or more isolation structures, wherein the third length is greater than 60% the thickness, wherein the second p+ doped region has a fourth length that extends parallel to the one or more isolation structures, and wherein the fourth length is greater than 60% the thickness.

4. The image sensor defined in claim 3, further comprising:
a third n-type doped region in the semiconductor substrate, wherein the third n-type doped region overlaps the p-type doped region in a direction orthogonal to the first surface.

5. The image sensor defined in claim 4, wherein the third n-type doped region overlaps the first and second n-type doped regions in the direction orthogonal to the first surface.

6. The image sensor defined in claim 4, wherein the first, second, and third n-type doped regions collectively have a U-shaped cross-section.

7. The image sensor defined in claim 4, further comprising:
a transfer gate between the first and second opposing surfaces, wherein the transfer gate has a length that extends in the direction orthogonal to the first surface.

8. The image sensor defined in claim 4, further comprising:
a transfer gate on the first surface, wherein the transfer gate has a length that extends parallel to the first surface.

9. The image sensor defined in claim 1, further comprising:
a color filter element that overlaps the photodiode; and
a microlens that overlaps the color filter element, wherein the second surface is interposed between the first surface and the semiconductor substrate.

10. The image sensor defined in claim 9, wherein the first surface is a front surface of the semiconductor substrate and wherein the second surface is a back surface of the semiconductor substrate.

11. The image sensor defined in claim 9, wherein the first and second n-type doped regions terminate within 0.5 microns of the second surface.

12. A method, comprising:
forming one or more trenches in a semiconductor substrate, wherein the semiconductor substrate has first and second opposing surfaces and one or more side surfaces, wherein the one or more side surfaces are orthogonal to the first and second surfaces, and wherein the one or more side surfaces define the one or more trenches;
implanting n-type dopants through the one or more side surfaces;
after implanting the n-type dopants through the one or more side surfaces, implanting p-type dopants through the one or more side surfaces; and
after implanting the p-type dopants through the one or more side surfaces, implanting additional n-type dopants through the first surface.

13. The method defined in claim 12, wherein implanting the n-type dopants through the one or more side surfaces comprises implanting the n-type dopants through the one or more side surfaces using plasma assisted doping.

14. The method defined in claim 13, wherein implanting the p-type dopants through the one or more side surfaces comprises implanting the p-type dopants through the one or more side surfaces using plasma assisted doping.

15. The method defined in claim 12, wherein implanting the n-type dopants through the one or more side surfaces comprises implanting the n-type dopants through the one or more side surfaces using a linear ion beam.

16. The method defined in claim 15, wherein implanting the p-type dopants through the one or more side surfaces comprises implanting the p-type dopants through the one or more side surfaces using a linear ion beam.

17. The method defined in claim 12, further comprising:
after implanting the n-type dopants through the one or more side surfaces, annealing the semiconductor substrate.

18. The method defined in claim 12, further comprising:
after implanting the p-type dopants through the one or more side surfaces, annealing the semiconductor substrate.

19. An image sensor having an imaging pixel, the image sensor comprising:
a semiconductor substrate having first and second opposing surfaces and a thickness between the first and second surfaces that is greater than 4 microns;
one or more isolation structures that extend around a periphery of the imaging pixel;
one or more interlayer dielectric layers that are adjacent to the first surface, wherein the second surface is interposed between the first surface and the color filter element;
a photodiode for the imaging pixel, wherein the photodiode comprises:
a first n-type doped region in the semiconductor substrate, wherein the first n-type doped region has a first length that extends parallel to the one or more isolation structures and wherein the first n-type doped region terminates within 0.5 microns of the second surface;
a second n-type doped region in the semiconductor substrate, wherein the second n-type doped region has a second length that extends parallel to the one or more isolation structures and wherein the second n-type doped region terminates within 0.5 microns of the second surface; and
a p-type doped region in the semiconductor substrate that is interposed between the first and second n-type doped regions; and
a color filter element for the imaging pixel that overlaps the photodiode; and
a microlens for the imaging pixel that overlaps the color filter element.

20. The image sensor defined in claim 19, further comprising:
a third n-type doped region in the semiconductor substrate, wherein the third n-type doped region overlaps the p-type doped region, the first n-type doped region, and the second n-type doped region in a direction orthogonal to the first surface.
